(19) United States
(12) Patent Application Publication
(10) Pub. No.: US 2010/0019800 A1
(43) Pub. Date: Jan. 28, 2010

(54) VERNIER PHASE ERROR DETECTION METHOD

(75) Inventor: Ping-Ying WANG, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/178,677

(22) Filed: Jul. 24, 2008

(51) Int. Cl. G01R 25/00; H03L 7/06

(52) U.S. Cl. 327/3; 327/157

(57) ABSTRACT

A vernier phase error detection method is provided. The method comprises providing a first signal having a first cycle T1, wherein T1=1/N T; providing a second signal having a second cycle T2, wherein T2=1/M T; aligning a rising edge of the second signal with a rising edge of the first signal; when a second data sampled by the second signal is different from a first data sampled by the first signal at the Xth second cycle, a phase error Ø is evaluated by the following equation: Ø=(N/2−X)*T1.

### BACKGROUND OF THE INVENTION

1. Field of the Invention

The invention relates to an electronic device, and more particularly to an electronic device for phase error detection.

2. Description of the Related Art

Phase-locked loop (PLL) devices are applied in frequency generators, wireless receivers, communication devices and the like. A phase detector is an essential element in a PLL device as a stable, high accurate clock signal output is highly related to the accuracy of the phase error from the phase detector. Phase detectors range from very simple to complex in design. An XOR logic gate makes a passable phase detector. When the two compared signals are completely in phase, the two equal inputs to the XOR gate will output a constant level of zero. When a phase difference occurs, the XOR gate will output a “1” for the duration of the difference in phase between signals. Integration of the output signal results in an analog voltage proportional to the phase difference. A phase detector can also be made from an analog multiplier, sample and hold circuit, charge pump or a logic circuit consisting of flip-flops. These phase detectors have more desirable properties such as better accuracy at small phase differences or ability to phase lock to signals with large frequency mismatches. Although a complex phase detector generates a high accuracy phase error signal, the complex design causes unexpected errors, thus, a simple phase detector capable of performing high accuracy phase error detection method is desirable.

### BRIEF SUMMARY OF THE INVENTION

The invention provides a vernier phase error detection method comprising providing a first signal having a first cycle T1, wherein

$$T 1 = \frac{1}{N} T ;$$

providing a second signal having a second cycle T2, wherein

$$T 2 = \frac{1}{M} T ;$$

aligning a rising edge of the second signal with a rising edge of the first signal; when a second data sampled by the second signal is different from a first data sampled by the first signal at Xth second cycle, a phase error Ø is evaluated by the following equation:

$$Ø = ( \frac{N}{2} - X ) * T 1.$$

The invention provides a vernier phase detector comprising an alignment unit, a first sampler, a second sampler and a processing unit. The alignment unit aligns a rising edge of a first clock signal with a rising of a second clock signal. The first sampler is controlled by the first clock signal for sampling a data signal. The second sampler is controlled by the second clock signal for sampling the data signal. The processing unit determines a phase error signal between the first clock signal and the data signal, wherein when a first data sampled by the first sampler is different from a second data sampled by the second sampler, the processing unit determining the phase error signal based on the first clock signal and the second clock signal.

The invention provides a PLL device, comprising a phase detector, a charge pump circuit, a loop filter, a voltage controlled oscillator and a feedback divider. The phase detector comprises an alignment unit, a first sampler, a second sampler and a processing unit. The alignment unit aligns a rising edge of a first clock signal with a rising of a second clock signal. The first sampler is controlled by the first clock signal for sampling a data signal. The second sampler is controlled by the second clock signal for sampling the data signal. The processing unit determines a phase error signal between the first clock signal and the data signal, wherein when a first data sampled by the first sampler is different from a second data sampled by the second sampler, the processing unit determining the phase error signal based on the first clock signal and the second clock signal. The charge pump circuit outputs a current based on the phase error signal, and the loop filter then transfers the current into a voltage. The voltage controlled oscillator outputs an output signal based on the voltage. The feedback divider receives the output signal to generate the first clock signal, wherein the output signal is multiple of the first clock signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram of an embodiment of a phase detection method of the invention.

FIG. 2 is a schematic diagram of another embodiment of a phase detection method of the invention.

FIG. 3 is a block diagram of an embodiment of a vernier phase error detector of the invention.

FIG. 4 is a block diagram of an embodiment of a PLL device of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

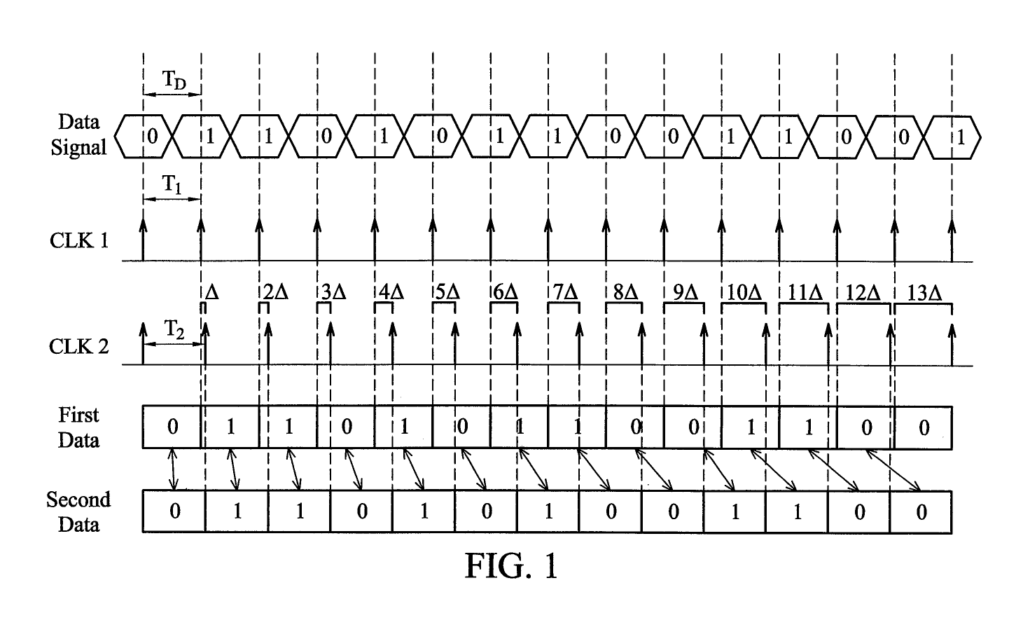

FIG. 1 is a schematic diagram of an embodiment of a vernier phase detection method of the invention. T_{D} represents the period of the data signal. T₁ is the period of the first clock CLK1. T₂ is the period of the second clock CLK2. In this embodiment, T_{D} is equal to T₁, and T₁ is slightly different from T₂. If the data signal is sampled at the center of each high and low level when the first clock CLK1 and the second clock CLK2 are aligned with each other, the data signal is locked to the first clock CLK1 or the second clock CLK2. If the data signal is not sampled at the center of each high and low level when the first clock CLK1 and the second clock CLK2 are aligned with each other, the data signal is not locked to the first clock CLK1. A phase error between the data signal and the first clock CKL1 can be detected.

With reference to FIG. 1, T₂ is slightly longer than T₁, so after a clock cycle, the sampling edge of the second clock CLK2 slightly lags that of the first clock CLK1. The phase deviation caused by the lag is represented by Δ. After another clock cycle, the second clock CLK2 further lags the first clock CLK1 by 2Δ, and so on. In this embodiment, when the second clock CLK2 lags the first clock by 13Δ, the first clock CLK1 and the second clock CLK2 are realigned. It can be found that T₁/T₂=13/14.

If the data signal is locked to the first clock CLK1 as shown in FIG. 1, the sampling edge of the first clock CLK1 is at the center of the high or low level when the alignment between the first clock CLK1 and the second clock CLK2 occurs. In this situation, the same data value (0 or 1) is sampled by the first clock CLK1 and the second clock CLK2 until the phase deviation reaches 7Δ. That is, a data value transition occurs when the phase deviation increases from 6Δ to 7Δ. This is because the phase deviation of 6.5Δ is about T_{D}/2, the second clock CLK2 starts to sample the next value of the data signal by crossing the transition.

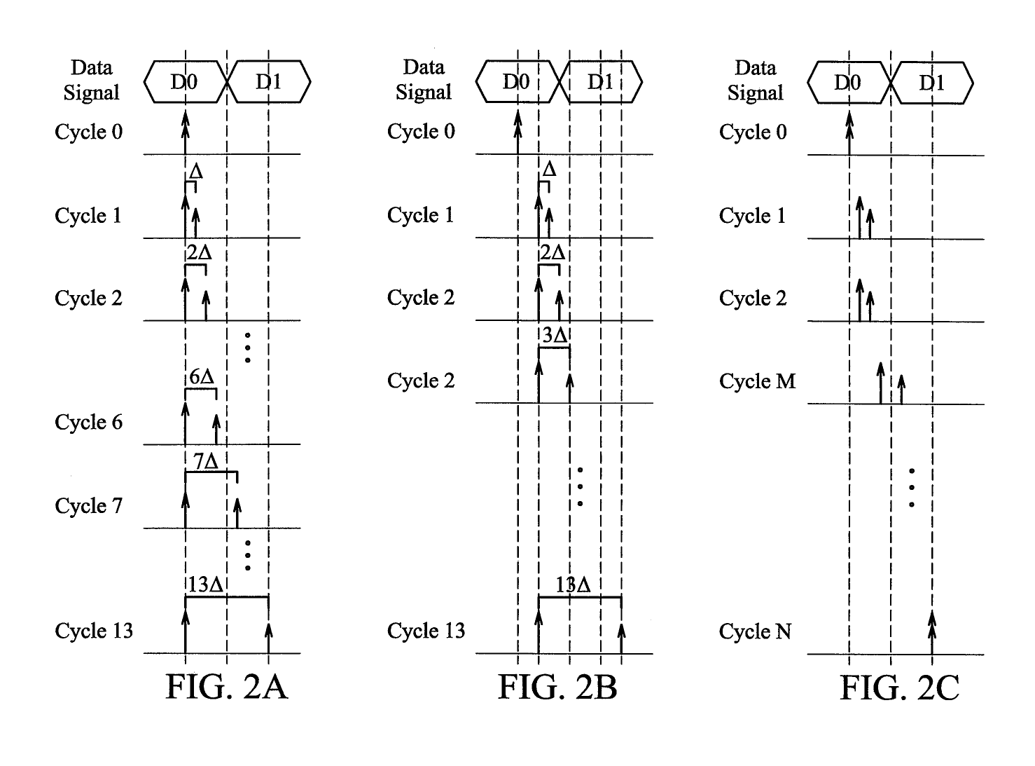

FIG. 2A, FIG. 2B, and FIG. 2C show the shifts of sampling edges for each clock cycle. With reference to FIG. 2A, during the clock cycle 0, the first clock CLK1 and the second clock CLK2 are aligned at the center of D0. This is a lock status. During the clock cycle 1, the second clock CLK2 deviates from the first clock CLK1 by Δ. During the clock cycle 2, the second clock CLK2 deviates from the first clock CLK1 by 2Δ, and so on. During the clock cycle 7, the second clock CLK2 has crossed the transition edge of D0 and D1, so the second clock CLK2 samples D1 instead of D0. If D0 has a different value from D1 during the clock cycle 7, the first clock CLK1 and the second clock CLK2 will have different sampled values.

With reference to FIG. 2B, during the clock cycle 0, the first clock CLK1 and the second clock CLK2 are not aligned at the center of D0. This is not a lock status. During the clock cycle 1, the second clock CLK2 deviates from the first clock CLK1 by Δ. During the clock cycle 2, the second clock CLK2 deviates from the first clock CLK1 by 2Δ, and so on. During the clock cycle 3, the second clock CLK2 has crossed the transition edge of D0 and D1, so the second clock CLK2 samples D1 instead of D0. If D0 has a different value from D1 during the clock cycle 3, the first clock CLK1 and the second clock CLK2 will have different sampled values.

It can be found from FIG. 2A and FIG. 2B that by detecting the number of clock cycles when the second clock CLK2 crosses the data transition edge, one can know whether the data signal is in a lock status. If the data signal is in a lock status, the detected number of clock cycles is corresponding to T_{D}/2. If the data signal is not in a lock status, the detected number of clock cycles is not corresponding to T_{D}/2. The phases of the first clock CLK1 and the second clock CLK2 can be further adjusted to make the data signal locked by the first clock CLK1 or the second clock CLK2. For example, in FIG. 2B, if the first clock and the second clock are shifted left by 4Δ, then D0 can be sampled at the center when the first clock CLK1 and the second clock CLK2 are aligned.

However, T_{D} need not be the same as T₁. With reference to FIG. 2C, during the clock cycle 0, the first clock CLK1 and the second clock CLK2 are aligned at the center of D0. This is a lock status. It is noted that the period of first clock CLK1 or the second clock CLK2 is different from that of the data signal, so that during the clock cycle 1, both the first clock CLK1 and the second clock CLK2 are not at the center of D0, and the second clock CLK2 deviates from the first clock CLK1 by Δ. During the clock cycle 2, the second clock CLK2 deviates from the first clock CLK1 by 2Δ, and so on. During the clock cycle M, the second clock CLK2 has crossed the transition edge of D0 and D1, so the second clock CLK2 samples D1 instead of D0. If D0 has a different value from D1 during the clock cycle M, the first clock CLK1 and the second clock CLK2 will have different sampled values. In this embodiment, during the clock cycle N, the first clock CLK1 and the second clock CLK2 are realigned at the center of D1.

FIG. 5 is a diagram showing the relationship between the data signal, the first clock CLK1 and the second clock CLK2. For each clock cycle, the first clock CLK1 gets a further phase shift T_{D}/P with respect to the rising edge of the data signal, where P is a natural number. Similarly, for each clock cycle, the second clock CLK2 gets a further phase shift T_{D}/Q with respect to the rising edge of the data signal, where Q is a natural number. That is, for each clock cycle, the second clock CLK2 gets a further phase shift T_{D}/Q−T_{D}/P with respect to the first clock CLK1. Every P first clock cycles (or every Q second clock cycles), the first clock CLK1 and the second clock CLK2 are realigned. If the realignment occurs at the center of the high level or low level of the data signal, it is a lock status. It is preferred that P and Q are relatively prime. One convenient embodiment is Q=P+1 or P−1. However, even if P and Q are not relatively prime, the first clock CLK1 and the second clock CLK2 will eventually be realigned. The realignments can be detected to determine whether a lock status is reached.

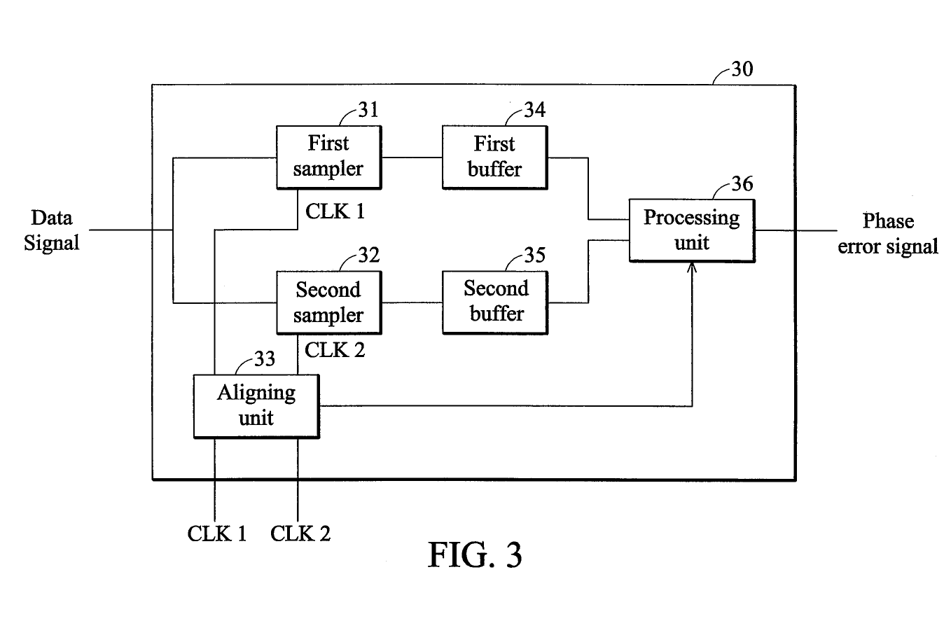

FIG. 3 is a block diagram of an embodiment of a vernier phase error detector. The vernier phase error detector 30 comprises a first sampler 31, a second sampler 32, an aligning unit 33, and a processing unit 36. The aligning unit 33 outputs the first clock CLK1 and the second clock CLK2 to sample the data signal. The aligning unit 33 also determines the time when the first clock CLK1 and the second clock CLK2 are aligned. The processing unit 36 determines a phase error according to the first sampled value (sampled by the first clock CLK1), the second sampled value (sampled by the second clock CLK2), and the alignments of the first clock CLK1 and the second clock CLK2. The vernier phase error detector 30 can further comprise a first buffer for storing the first sampled value and a second buffer for storing the second sampled value.

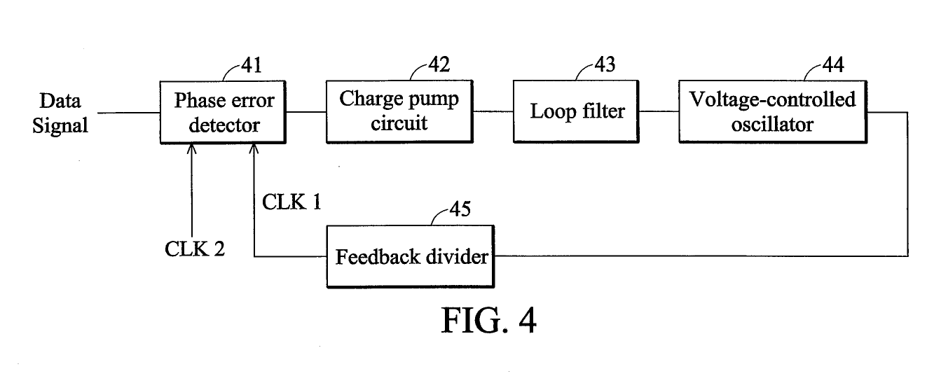

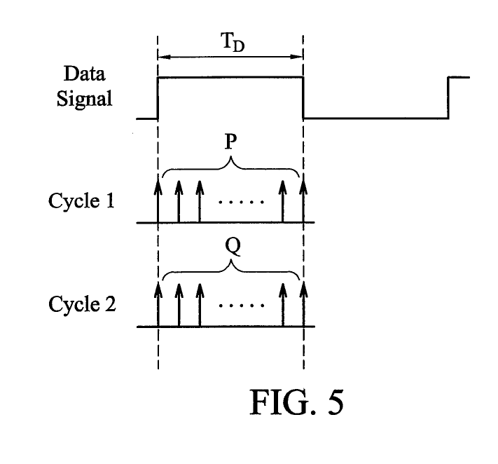

FIG. 4 is a block diagram of an embodiment of a PLL device of the invention. The PLL comprises a phase error detector 41, a charge pump circuit 42, a loop filter 43, a voltage-controlled oscillator 44 and a feedback divider 45. The phase error detector 41 is described in FIG. 3, for brevity, description of like structures are omitted. The charge pump circuit 42 converts a phase error signal from the phase error detector 41 into a charge current for charging or discharging the loop filter 43. The loop filter 43 limits the rate of charge of a capacitor therein to generate a voltage corresponding to the phase error signal, and the voltage-controlled oscillator 44 then generates an output signal based on the voltage. The feedback divider 45 receives the output signal to generate a first clock signal CLK1, wherein the frequency of the output signal is multiple of the frequency of the first clock signal. In this embodiment, the frequency of the output signal is also a multiple of the frequency of the second clock. In another embodiment, the second clock signal is also generated by the feedback divider 45.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A vernier phase error detecting method, comprising:
providing a first clock and a second clock, wherein a first period of the first clock is different from a second period of the second clock, the first clock and the second clock are aligned every P first clock cycles and every Q second clock cycles, and P and Q are natural numbers;
sampling a data signal by the first clock to generate a first sampled value;
sampling the data signal by the second clock to generate a second sampled value;
comparing the first sampled value and the second sampled value to generate a comparison result;
detecting alignments of the first clock and the second clock; and
obtaining a phase error from the comparison result and the alignments of the first clock and the second clock.

2. The method as claimed in claim 1, wherein P and Q are relatively prime.

3. The method as claimed in claim 1, wherein Q=P+1.

4. The method as claimed in claim 1, wherein Q=P−1.

5. A vernier phase detector, comprising:
an aligning unit for providing a first clock and a second clock and detecting alignments of the first clock and the second clock, wherein a first period of the first clock is different from a second period of the second clock, and the first clock, the second clock are aligned every P first clock cycles and every Q second clock cycles, and P and Q are natural numbers;
a first sampler for sampling a data signal by the first clock;
a second sampler for sampling the data signal by the second clock; and
a processing unit for determining a phase error signal between the first clock signal and the data signal, wherein when a first data value sampled by the first sampler is different from a second data value sampled by the second sampler, the processing unit determining the phase error signal based on the first clock signal, the second clock signal, and the alignments of the first clock and the second clock.

6. The detector as claimed in claim 5, further comprising a first buffer storing the first data value and a second buffer storing the second data value.

7. The detector as claimed in claim 5, wherein P and Q are relatively prime.

8. The detector as claimed in claim 7, wherein Q=P+1.

9. The detector as claimed in claim 7, wherein Q=P−1.

10. A PLL device, comprising:
a phase detector, comprising:
an aligning unit for providing a first clock and a second clock and detecting alignments of the first clock and the second clock, wherein a first period of the first clock is different from a second period of the second clock, and the first clock, the second clock are aligned every P first clock cycles and every Q second clock cycles, and P and Q are natural numbers;
a first sampler for sampling a data signal by the first clock;
a second sampler for sampling the data signal by the second clock; and
a processing unit for determining a phase error signal between the first clock signal and the data signal, wherein when a first data value sampled by the first sampler is different from a second data value sampled by the second sampler, the processing unit determining the phase error signal based on the first clock signal, the second clock signal, and the alignments of the first clock and the second clock;
a charge pump circuit outputting a current based on the phase error signal;
a loop filter receiving and transferring the current into a voltage;
a voltage controlled oscillator receiving the voltage and outputting an output signal; and
a feedback divider receiving the output signal to generate the first clock signal, wherein a frequency of the output signal is multiple of a frequency of the first clock signal.

11. The PLL device as claimed in claim 10, further comprising a first buffer storing the first data value and a second buffer storing the second data value.

12. The PLL device as claimed in claim 10, wherein P and Q are relatively prime.

13. The PLL device as claimed in claim 12, wherein Q=P+1.

14. The PLL device as claimed in claim 12, wherein Q=P−1.
